(19) United States
(12) Patent Application Publication
(10) Pub. No.: US 2005/0253277 A1
(43) Pub. Date: Nov. 17, 2005

(54) Film for protecting mother glass for flat panel display and use thereof

(76) Inventors: Takeshi Yamanaka, Ibaraki-shi (JP); Minoru Hanaoka, Ibaraki-shi (JP); Yoshiki Kobayashi, Ibaraki-shi (JP); Hideaki Sakakura, Singapore (SG)

Correspondence Address: KNOBBE MARTENS OLSON & BEAR LLP, 2040 MAIN STREET, FOURTEENTH FLOOR, IRVINE, CA, 92614, US

(21) Appl. No.: 11/109,568

(22) Filed: Apr. 19, 2005

(30) Foreign Application Priority Data
Apr. 21, 2004 (JP) 2004-125545

(51) Int. Cl. H01L 23/48

(52) U.S. Cl. 257/778

(57) ABSTRACT

An object of the present invention is to provide a surface protecting film which dramatically improves an efficiency of transporting and storing a mother glass, has better peelability from an adherend when peeled without polluting a mother glass surface, and gives reinforcing effect by adopting a pressure-sensitive adhesive protecting film, and use thereof. This invention relates to a film for protecting a mother glass for a flat panel display having a pressure-sensitive adhesive layer on one side of a film substrate, wherein a surface roughness Ra of the pressure-sensitive adhesive layer is 0.2 μm or smaller, and a surface roughness Rz is 1.0 μm or smaller, and wherein the pressure-sensitive adhesive layer comprises a crosslinked copolymer containing a (meth)acrylic acid ester monomer and a vinyl-based monomer having a functional group as a component, and a glass transition temperature of the copolymer obtained by a Fox's equation is −25 to −10° C.

### BACKGROUND OF THE INVENTION

1. Field of the Invention

The present invention relates to a film for protecting a mother glass for a flat panel display, which protects a surface of a mother glass used for manufacturing various display devices, and use thereof, and the present invention is useful as technique, particularly, for conveying a mother glass with protection.

2. Description of the Related Art

For manufacturing a flat panel display such as a liquid crystal display, a plasma display panel and an organic EL display, a glass substrate is used. A glass plate manufactured in a factory is distributed (conveyed) as a mother glass, and this is processed into the glass substrate. When a glass surface is flawed due to conveyance, storage, transport during shipping, and storage at customers of a mother glass, this becomes a cause for reduction in a yield, and adverse influence on quality, therefore, such a retaining form that glass surfaces are not contacted is usually adopted.

For this reason, regarding conveyance and storage of a mother glass, contacting to surfaces of mother glasses is prevented by forming a slit-like groove and fixing a mother glass in the groove one by one and, thereupon, a foamed molded article is mainly utilized.

Packaging with molded articles which are currently used are roughly classified into two kinds. One is a box-type packaging container, in which a groove is formed in a box, and sealing packaging is performed by fixing a mother glass therein, and closing it with a lid. The other is also called L-letter pad, and a groove for fixing a mother glass is formed inside an L-letter type foamed molded article, and uses a method of arranging this L-letter type foamed molded article on four corners of fundamental packaging number (e.g. 20)-bundled mother glasses, and fixing them by binding with a tape.

Any packaging state has advantages and defects and, for example, from a viewpoint of a clean degree, an L-letter type foamed molded article is advantageous in washing easiness, but from a viewpoint of stability and easy handling of packaging, a box-type is advantageous and, finally, both types were used for different purposes depending on the purpose and preference order of use by customers.

However, in recent years, with scale up of a flat panel display, scale up of a mother glass has been also demanded, it has become difficult to response to conveyance and storage of a scaled up mother glass, by the aforementioned packaging form. Specifically, clean washing of a large foamed molded article is difficult. In an L-letter type packaging material, since a vinyl bag is used for closing wrapping, it has become difficult to obtain the material having a controlled clean degree. In addition, also regarding a cost, in such the method, the number of glasses to be placed in a space per unit volume is small, and a piling efficiency is very low, leading to increase in a distribution cost. In addition, this foamed molded article itself approaches a limit of a foaming precision because of increase in a size. Alternatively, since a weight of a mother glass has been greatly increased, there is a problem on a strength and, for this reason, the article is reinforced with a metal bar. This becomes complicated and large scale and, as a result, the article is difficult to be available, and is becoming highly expensive.

In order to solve this problem, a conveying method of packaging a mother glass with a plastic film, and piling it has been proposed (see Japanese patent laid-open application publication JP-A No. 11-1205, JP-A No. 2003-237833, and JP-A No. 2003-273189). In particular, JP-A No. 11-1205 discloses prevention of occurrence of static electricity and scratch by subjecting a film surface to fine unevenly processing.

However, in a non-adhesive sheet or package like these methods, it is thought that rubbing with a mother glass and slippage easily occur with scale up of a mother glass. For this reason, even when an unevenly-processed film is used, there is a limit on prevention of occurrence of static electricity and scratch of a mother glass. In addition, in a non-adhesive sheet or package, a dust easily enters, so it is difficult to say that handling property of a mother glass and a laminate thereof is better, and there is little glass reinforcing effect.

On the other hand, a method of placing a plastic film (see JP-A No. 2003-226354) or a paper spacer between mother glasses has been performed. However, in this method, there has been feared a problem of pollution with an additive contained in a plastic film or a paper powder when a spacer is peeled from a mother glass.

### SUMMARY OF THE INVENTION

Accordingly, an object of the present invention is to provide a surface protecting film which dramatically improves an efficiency of transporting and storing a mother glass, has better peelability from an adherend when peeled without polluting a surface of a mother glass, and gives reinforcing effect, by adopting a pressure-sensitive protecting film, and use thereof.

In order to attain the aforementioned object, the present inventors intensively studied, particularly, pollution preventing property of a mother glass surface, and found out that the aforementioned object can be attained by sufficiently reducing a surface roughness Ra and a surface roughness Rz of a pressure-sensitive adhesive layer using a pressure-sensitive adhesive having a glass transition temperature of a particular range, which resulted in completion of the present invention.

That is, a film for protecting a mother glass for a flat panel display of the present invention is a film for protecting a mother glass for a flat panel display having a pressure-sensitive adhesive layer on one side of a film substrate, wherein a surface roughness Ra of the pressure-sensitive adhesive layer is 0.2 μm or smaller, and a surface roughness Rz is 1.0 μm or smaller, and wherein the pressure-sensitive adhesive layer comprises a crosslinked copolymer containing a (meth)acrylic acid ester monomer and a vinyl-based monomer having a functional group, and a glass transition temperature of the copolymer obtained by a Fox's equation is −25 to −10° C.:
1/Tg=Σ(Wn/Tgn) Fox's equation:
[wherein Tg(K) represents a glass transition temperature of a copolymer, Wn(−) represents a weight fraction of each monomer, Tgn(K) represents a glass transition temperature of a homopolymer of each monomer, and n represents a kind of each monomer]

In the present invention, the “mother glass for a flat panel display” refers to a glass plate before processing into various products in the state where it can be distributed, and which is used for manufacturing a flat panel display. Examples of the flat panel display include display devices such a liquid crystal display, a plasma display panel, and an organic EL display.

According to the protecting film of the present invention, since a pressure-sensitive adhesive protecting film is adopted, rubbing with a mother glass and slippage hardly occur, and a dust hardly enters, therefore, the film is effective for preventing a scratch, and handling property of a mother glass and a laminate thereof becomes better. As a result, an efficiency of transporting and storing a mother glass can be dramatically improved. In addition, since physical reinforcing effect is also obtained, flexion of a mother glass can be prevented, and also against scale up of a mother glass, flexion and cracking can be effectively prevented. Moreover, by controlling a surface roughness Ra of a pressure-sensitive adhesive layer and a surface roughness Rz in the aforementioned range using a pressure-sensitive adhesive having a glass transition temperature in a particular range, when peeled, peelability from an adherend becomes better without polluting a mother glass surface.

In the forgoing, it is preferable that a separator having a surface roughness Ra of a releasing surface of 0.21 μm or smaller, and a surface roughness Rz of 1.0 μm or smaller is attached to and wound in a roll manner on the pressure-sensitive adhesive layer. By using such the separator, when a protecting film is used after peeling, a surface roughness Ra of a pressure-sensitive adhesive layer and a surface roughness Rz can be controlled in the aforementioned range, and the aforementioned action and effect can be obtained more surely.

On the other hand, a method of conveying a mother glass of the present invention is characterized in that a pressure-sensitive adhesive side of the film for protecting a mother glass for a flat panel display is attached to at least one side of a mother glass, and laminating plurality thereof thereof to be conveyed. In the method of conveying a mother glass of the present invention, since the protecting film of the present invention exerting the aforementioned action and effect is used, an efficiency of transporting and storing a mother glass is dramatically improved, peelability from an adherend when peeled becomes better without polluting a mother glass surface, and reinforcing effect is also obtained.

In the forgoing, when a plurality of mother glasses with the protecting film attached thereto are laminated, an unevenly-processed film can intervene. In this case, by reducing adherability between mother glasses with the protecting film attached thereto, handling property of a mother glass can be improved more. Generally, when a rear side of a protecting film is unevenly-processed, unevenly is easily generated also on a pressure-sensitive adhesive side, and a problem of a remaining adhesive easily arises by increase in a surface roughness. For this reason, intervening of an unevenly-processed film without unevenly processing of a substrate of a protecting film is particularly effective in the present invention.

On the other hand, a mother glass with a protecting film of the present invention is such that a pressure-sensitive adhesive side of the film for protecting a mother glass for a flat panel display of the present invention is attached to at least one side of a mother glass. In addition, a mother glass laminate of the present invention is such that a pressure-sensitive adhesive side of the film for protecting a mother glass for a flat panel display is attached to at least one side of a mother glass, and a plurality of laminates thereof are laminated. According to them, since the protecting film exerting the aforementioned action and effect is attached, an efficiency of transporting and storing a mother glass is dramatically improved and, moreover, peelability from an adherend when peeled becomes better without polluting a mother glass surface is also improved, and reinforcing effect is also obtained.

### BRIEF DESCRIPTION OF THE DRAWINGS

FIG. 1 is a cross-sectional view showing one example of the state of using the film for protecting a mother glass for a flat panel display of the present invention.

FIG. 2 is a cross-sectional view showing other example of the state of using the film for protecting a mother glass for a flat panel display of the present invention.

### DESCRIPTION OF THE PREFERRED EMBODIMENTS

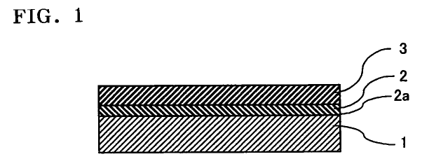

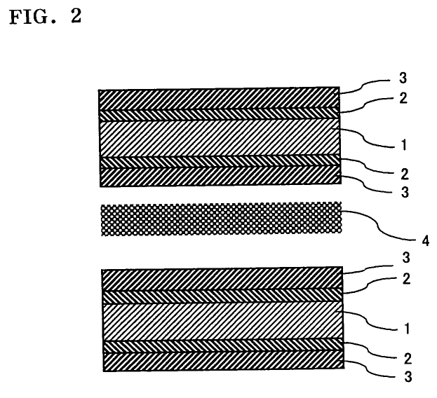

Embodiments of the present invention will be explained below by referring to the drawings. FIG. 1 is a cross-sectional view showing one example of the state of using the film for protecting a mother glass for a flat panel display of the present invention, and FIG. 2 is a cross-sectional view showing other example of the state of using the film for protecting a mother glass for a flat panel display of the present invention.

The film for protecting a mother glass for a flat panel display of the present invention has a pressure-sensitive adhesive layer 2 on one side of a film substrate 3 as shown in FIG. 1, and is used by attaching its pressure-sensitive adhesive side 2a to at least one side of a mother glass 1. This pressure-sensitive adhesive layer 2 contains a crosslinked copolymer containing a (meth)acrylic acid ester monomer and a vinyl-based monomer having a functional group as a component.

Examples of the (meth)acrylic acid ester monomer include (meth)acrylic acid alkyl ester such as methyl acrylate, methyl methacrylate, ethyl acrylate, ethyl methacrylate, propyl acrylate, propyl methacrylate, butyl acrylate, butyl methacrylate, hexyl acrylate, hexyl methacrylate, octyl acrylate, octyl methacrylate, nonyl acrylate, nonyl methacrylate, dodecyl acrylate, and dodecyl methacrylate.

These alkyl parts may be straight or branched. These (meth)acrylic acid ester monomers may be used alone, or in a combination of two or more.

Examples of the vinyl-based monomer having a functional group include vinyl-based monomers having a carboxyl group such as acrylic acid, methacrylic acid, itaconic acid, crotonic acid, and maleic acid; vinyl-based monomers having a hydroxyl group such as 2-hydroxyethyl (meth)acrylate, 2-hydroxypropyl (meth)acrylate, and 2-hydroxyhexyl (meth)acrylate.

These vinyl-based monomers may be used alone, or in a combination of two or more.

A content of the vinyl-based monomer having a functional group is preferably 0.5 to 10 mol % in all monomers constituting a copolymer. When the content is less than 0.5 mol %, a copolymer cannot be sufficiently crosslinked with a crosslinking agent as described later, a solvent-insoluble fraction of a pressure-sensitive adhesive layer is decreased, and there is a tendency that adhesive remaining on a mother glass surface easily occurs upon peeling of a protecting film. On the other hand, when the content exceeds 10 mol %, there is a tendency that initial adhering property is inferior. From such a point of view, the content is preferably 1 to 8 mol %. In the present invention, other vinyl-based monomer containing no functional group may be used as a further copolymerization component.

A copolymer of the (meth)acrylic acid ester monomer and the vinyl-based monomer having a functional group are prepared by the previously known method. If necessary, a polymerization initiator can be used.

In the present invention, a glass transition temperature of the copolymer obtained by a Fox's equation is −25 to −10° C., preferably −23 to −12° C. When the glass transition temperature is lower than −25° C., an adhering strength becomes too high, and peeling from a mother glass becomes difficult. Conversely, when the glass transition temperature is higher than −10° C., an initial adhering strength of a pressure-sensitive adhesive layer obtained from such the copolymer at a normal temperature is deficient, and a role of function of protecting a mother glass cannot be exerted.
1/Tg=Σ(Wn/Tgn) Fox's equation:
[wherein Tg(K) represents a glass transition temperature of a copolymer, Wn(−) represents a weight fraction of each monomer, Tgn(K) represents a glass transition temperature of a homopolymer of each monomer, and n represents a kind of each monomer]

Herein, a glass transition temperature Tgn(K) of a homopolymer of each monomer is known in various references. In the present invention, regarding each monomer of Table 1, a value of Table 1 is adopted. In the case of other monomers having no value in references or having inconsistent values in references, a value measured by general thermal analysis, for example, differential calorimetry or a dynamic viscoelasticity measuring method is adopted.

TABLE 1

| Monomer | Abbreviation | Homopolymer Tg(K) |
|---|---|---|
| Methyl acrylate | MA | 281 |
| Ethyl acrylate | EA | 251 |
| Isopropyl acrylate | i-PA | 268 |
| n-Butyl acrylate | BA | 219 |
| 2-Ethylhexyl acrylate | 2EHA | 203 |
| Methyl methacrylate | MMA | 378 |
| Ethyl methacrylate | EMA | 338 |
| Isopropyl methacrylate | i-PMA | 354 |
| n-Butyl methacrylate | BMA | 293 |
| Isobutyl methacrylate | i-BMA | 340 |
| n-Hexyl methacrylate | HMA | 268 |
| Lauryl methacrylate | LMA | 208 |
| Acrylic acid | AA | 379 |
| Methacrylic acid | MAA | 403 |
| 2-Hydroxyethyl acrylate | 2HEA | 258 |
| Hydroxypropyl acrylate | HPA | 266 |
| 2-Hydroxyethyl methacrylte | 2HEMA | 328 |
| Hydroxypropyl methacrylate | HPMA | 299 |
| Maleic acid | IA | 403 |
| Acrylamide | AAm | 426 |
| Diacetoneacrylamide | DAAM | 338 |
| Glycidyl methacrylate | GMA | 314 |
| Styrene | St | 373 |
| Vinyl acetate | Vac | 303 |
| Acrylonitrile | AN | 373 |

In the present invention, a pressure-sensitive adhesive layer is constructed by crosslinking the aforementioned copolymer with a crosslinking agent, and crosslinking is preferably performed by a reaction of a functional group of the vinyl-based monomer and a crosslinking agent.

The crosslinking agent is a compound having at least two or more groups which can react with a functional group of the vinyl-based monomer. Examples include polyfunctional isocyanate compounds such as trimethylolpropane tolylene diisocyanate, and methylene diisocyanate compound; polyglycidylamine compounds such as tetraglycidyl metaxylilenediamine, tetraglycidyl-1, 3-bisaminomethylcyclohexane, tetraglycidyldiaminodiphenylmethane, triglycidyl p-aminophenol, diglycidylaniline, and diglycidyl o-toluidine. These crosslinking agents may be used alone, or in a combination of two or more.

An amount of the crosslinking agent to be blended depends on a content of a vinyl-based monomer having a functional group which is used in the copolymer, and is preferably 1 to 10 parts by weight, more preferably 2 to 8 parts by weight relative to 100 parts by weight of a copolymer. When the blending amount is less than 1 part by weight, a copolymer is not sufficiently crosslinked, and a solvent-insoluble fraction of a pressure-sensitive adhesive layer is decreased, so that there is a tendency that adhesive remaining easily occurs. Conversely, when the blending amount exceeds 10 parts by weight, there is a tendency that an initial adhering strength of a pressure-sensitive adhesive layer is deficient.

Further, the previously known various tackifier, and the previously known various additives such as an antistatic agent, a surface lubricant, a leveling agent, an antioxidant, a corrosion preventing agent, a light stabilizer, an ultraviolet absorbing agent, a polymerization inhibitor, a silane coupling agent, an inorganic or organic filler, and a powder, a particle and a foil such as a metal powder and a pigment can be appropriately added to a pressure-sensitive adhesive layer.

As a film substrate used in the surface protecting film of the present invention, a plastic film prepared from the generally used polypropylene, high density polyethylene, low density polyethylene, medium density polyethylene, linear low density polyethylene, polyethylene terephthalate, and ethylene-α-olefin copolymer can be used, being not limiting.

A thickness of a film substrate is preferably 10 to 300 μm, more preferably 30 to 100 μm. When a thickness is in such the range, also in the case where used in a large size mother glass, handling property such as attaching and peeling of a protecting film, and reinforcing performance of a glass become better, and the effect of preventing a flaw at glass processing or conveyance is obtained.

As a method of forming a pressure-sensitive adhesive layer on a film substrate, the previously known method is adopted, and a method of coating a solution of a pressure-sensitive adhesive composition containing the copolymer and a crosslinking agent, and crosslinking the composition by treatment such as heating is preferable.

In the present invention, it is important that a surface roughness Ra of the thus prepared pressure-sensitive adhesive layer is 0.2 μm or smaller, and a surface roughness Rz is 1.0 μm or smaller, thus, Ra and Rz of a pressure-sensitive adhesive layer surface satisfy both of the aforementioned numerical ranges. In the present invention, Ra and Rz are defined as values measured by the methods described later.

When a surface roughness Ra exceeds 0.2 μm, a particulate pollutant remains on a glass surface and, also when Rz exceeds 1.0 μm, a particulate pollutant remains on a glass surface. From such a point of view, it is desirable that Ra is preferably 0.1 μm or smaller, and Rz is preferably 0.5 μm or smaller.

In the present invention, in order to adjust a surface roughness of a pressure-sensitive adhesive layer in the aforementioned numerical value range, there can be exemplified a method of attaching a film, a sheet, or a separator (a surface form of these films can set a surface roughness of a pressure-sensitive adhesive layer in a particular range) which can set a surface roughness of a pressure-sensitive adhesive layer in the aforementioned numerical value range to a pressure-sensitive adhesive layer after formation of a pressure-sensitive adhesive layer, and a method of setting a surface roughness of a pressure-sensitive adhesive layer surface in the aforementioned range upon winding into a roll by controlling a surface roughness of a substrate rear side. Thereupon, it is preferable that a surface roughness Ra of a surface to be attached to a pressure-sensitive adhesive layer is 0.2 μm or smaller, and a surface roughness Rz is 1.0 μm or smaller, and it is more preferable that Ra is 0.1 μm or smaller, and Rz is 0.5 μm or smaller.

In the protecting film of the present invention, it is preferable that a separator having the aforementioned surface roughness is attached to a releasing side, and this is wound in a roll manner. As a substrate of a separator, there are a paper and a plastic film, and a plastic film is suitably used because its surface smoothness is excellent.

The film used for the separator is not particularly limited as far as it is a film which can protect the pressure-sensitive adhesive layer, and examples include a polyethylene film, a polypropylene film, a polybutene film, a polybutadiene film, a polymethylpentene film, a polyvinyl chloride film, a vinyl chloride copolymer film, a polyethylene terephthalate film, a polybutylene terephthalate film, a polyurethane film, and an ethylene-vinyl acetate copolymer film. A thickness of a separator is usually about 5 to 200 μm, preferably about 10 to 100 μm. A pressure-sensitive adhesive layer attaching side of a separator is appropriately subjected to releasing agent treatment using a silicone releasing agent, a fluorine releasing agent, a long chain alkyl releasing agent or a fatty acid amide releasing agent, or a silica powder.

From a viewpoint of adherability to a glass surface, a thickness of a pressure-sensitive adhesive layer of the protecting film of the present invention is preferably 0.1 to 30 μm, more preferably 0.5 to 20 μm.

On the other hand, as shown in FIG. 1, the mother glass with a protecting film of the present invention is such that a pressure-sensitive adhesive side 2a of the aforementioned protecting film is attached to at least one side of a mother glass 1. FIG. 2 shows the case where a protecting film is attached to both sides.

As a mother glass 1 for a flat panel display, glasses prepared by a downflow method, a fusion method or a floating method can be suitably used. A surface roughness Rmax is preferably 30 nm or smaller, particularly preferably 10 nm or smaller. As a composition of a glass, an aluminosilicate glass, a sodaaluminosilicate glass, a sodalime glass, and a borosilicate glass are suitable. In particular, even a mother glass used in manufacturing a display device such as a liquid crystal display, a plasma display panel, and an organic EL display can be made to respond to increase in a size in recent years by the present invention. The present invention is particularly effective for a mother glass having a thickness of 0.3 to 0.7 mm, and any of a long side and a short side of 1000 mm or larger.

Attachment of a protecting film can be performed by a method of attachment by pressing with a roller provided on a glass conveying line, a method using a hand roller, or a method of using a pressing laminator.

As shown in FIG. 2, a mother glass laminate of the present invention is such that a pressure-sensitive adhesive side 2a of the aforementioned protecting film is attached to at least one side of a mother glass 1, and a plurality of this are laminated. In an example (state before lamination) shown in the figure, when a mother glass 1 is laminated, a protecting film is attached on both sides thereof, and an unevenly-processed unevenly-treated film 4 intervenes.

In the present invention, although an unevenly-treated film 4 can be omitted, when an unevenly-treated film 4 intervenes, adherability between mother glasses with a protecting film attached thereto is reduced, and handling property of a mother glass can be further improved. In the present invention, since a clean degree of a surface of a mother glass 1 is maintained by a protecting film, a paper spacer or other cushion material may intervene.

Examples of an unevenly-treated film 4 include an embossed film, a foamed film, a film in which a surface has been roughened by sand blast, polishing roll or chemical treatment, and a film on which unevenness is formed by inclusion of a fine particle. An unevenly-treated film 4 may be porous.

A method of conveying a mother glass of the present invention is such that a pressure-sensitive adhesive side 2a of a protecting film is attached to at least one side of a mother glass 1 as described above, and a plurality of this are laminated, which is conveyed. The present method is the same as the previous method of conveying a mother glass except that the protecting film of the present invention is attached and, preferably, an unevenly-processed film intervenes, and any of the previous methods can be adopted.

### EXAMPLES

Examples specifically showing a feature and the effect of the present invention will be explained below. Evaluation items in Examples were measured as follows:

1) Glass Transition Temperature (Tg) of Copolymer

The temperature was obtained by the following Fox's equation:
1/Tg=Σ(Wn/Tgn) Fox's equation:
[wherein Tg(K) represents a glass transition temperature of a copolymer, Wn(−) represents a weight fraction of each monomer, Tgn(K) represents a glass transition temperature of a homopolymer of each monomer, and n represents a kind of each monomer]. As Tgn(K), a value of Table 1 was adopted.

2) Initial Adhering Strength

A surface protecting film was attached to a mother glass for a liquid crystal substrate at a pressure of 8 kg/cm (in terms of linear pressure) and a rate of 0.3 m/min using a laminator. After allowing to stand at room temperature for 30 minutes, a surface protecting film was peeled at a tensile rate of 0.3 m/min and an angle of 180°, and a peeling force at that time was adopted as an initial adhering strength. A mother glass for a liquid crystal substrate was formed by a downdrawing method, and its surface roughness Rmax at polishing free was 10 nm or smaller. And, a composition of a glass was an alkali-free aluminosilicate glass.

3) Peeling Strength

A surface protecting film was attached to a mother glass for a liquid crystal substrate at a pressure of 8 kg/cm (in terms of linear pressure) and a rate of 0.3 m/min using a laminator. Thereafter, this was stored in a hot air circulating dryer at 50° C. for 3 days, and cooled to room temperature, and a surface protecting film was peeled at a tensile rate of 0.3 m/min and an angle of 180°, and a peeling force at that time was measured.

4) Measurement of Surface Roughness

In order to investigate a roughness of a pressure-sensitive adhesive surface of a surface protecting film, observation was performed using a surface shape measuring equipment. From measurement results, a center-line average surface roughness (Ra) and a ten-point average surface roughness (Rz) were obtained. A sample was cut into about 1 cm square, this was fixed on a glass plate with a double-sided tape, and subjected to vapor staining treatment with a 2% aqueous ruthenic acid solution at room temperature for 10 minutes, which was subjected to surface shape measurement.

As the surface shape measuring equipment, KLA-Tencor P-11 was used, and the measuring conditions were: measuring length; 2000 μm, scanning rate; 400 μm/sec, scanning time; 100 times(20 μm intervals), load; 3 mg.

5) Measurement of Particulate Residue on Adherend Surface

As an adherend, a mother glass for a liquid crystal substrate was used. To this were attached various surface protecting films, each of the protecting films was peeled under the same condition as that of 3), and the number of particles of 0.28 to 10 μm was measured. As an analyzing apparatus, LS-5000 manufactured by Hitachi High-Tech Electronics Engineering Co., Ltd. was used. Almost all of particles were due to adhesive remaining.

### Example 1

68 Parts by weight of butyl acrylate, 29 parts by weight of methyl methacrylate, 3 parts by weight of 2-hydroxyethyl acrylate, 0.1 part by weight of 2,2′-azobis(2-amidinopropane) dichloride as a polymerization initiator, 1.5 parts by weight of sodium dodecylbenzenesulfonate as an emulsifying agent, and 100 parts by weight of water were placed into a reactor equipped with a cooling tube, a nitrogen introducing tube, a thermometer and a stirring device, emulsion polymerization was performed at 80° C. for 5 hours, and a pH was adjusted to 7.0 with 15% by weight of aqueous ammonia to obtain a copolymer emulsion having 50% by weight of a solid content.

This emulsion was salted out with hydrochloric acid, washed with water, and dried to obtain an acryl copolymer. This acryl copolymer was dissolved in toluene, and to this solution was added 3 parts by weight of trimethylolpropane tolylene diisocyanate relative to 100 parts by weight of a solid content of an acryl copolymer, followed by mixing to obtain a pressure-sensitive adhesive composition solution.

This solution was coated on a polyethylene film with a thickness of 60 μm having corona-treated one side so that a coated film after drying became 10 μm, this was dried in a dryer at 80° C. for 3 minutes, and a polyethylene film having a surface roughness Ra=0.01 μm and Rz=0.06 μm was attached thereon to obtain a surface protecting film.

### Example 2

According to the same manner as that of Example 1 except that a polyethylene film for attachment having a surface roughness of Ra=0.03 μm and Rz=0.17 μm was used, a surface protecting film was obtained.

### Comparative Example 1

According to the same manner as that of Example 1 except that a polyethylene film for attachment having a surface roughness of Ra=0.06 μm and Rz=0.33 μm was used, a surface protecting film was obtained.

### Comparative Example 2

47 Parts by weight of 2-ethylhexyl acrylate, 53 parts by weight of butyl methacrylate, 4 parts by weight of 2-hydroxyethyl acrylate, and 0.1 part by weight of azoisobisbutyronitrile as a polymerization initiator were placed into a reactor equipped with a cooling tube, a nitrogen introducing tube, a thermometer and a stirring device, and polymerization was performed in toluene at 50° C. for 24 hours to obtain a copolymer having 50% by weight of a solid content.

Then, 1.5 parts by weight of trimethylolpropane tolylene diisocyante was added relative to 100 parts by weight of a solid content of an acryl copolymer, followed by mixing to obtain a pressure-sensitive adhesive composition solution.

This solution was coated on a polyethylene film with a thickness of 60 μm having corona-treated one side so that a coated film after drying became 3 μm, this was dried in a dryer at 80° C. for 3 minutes to form a pressure-sensitive adhesive layer, and to this was attached a polyethylene film having a surface roughness of Ra=0.01 μm and Rz=0.06 μm to obtain a surface protecting film.

### Comparative Example 3

20 Parts by weight of 2-ethylhexyl acrylate, 80 parts by weight of butyl methacrylate, 4 parts by weight of 2-hydroxyethyl acrylate, and 0.1 part by weight of azoisobisbutyronitrile as a polymerization initiator were placed into a reactor equipped with a cooling tube, a nitrogen introducing tube, a thermometer, and a stirring device, and polymerization was performed in toluene at 50° C. for 24 hours to obtain a copolymer having 50% by weight of a solid content.

Then, 1.5 parts by weight of trimethylolpropane tolylene diisocyanate was added relative to 100 parts by weight of a solid content of an acryl copolymer, followed by mixing to obtain a pressure-sensitive adhesive composition solution.

This solution was coated on a polyethylene film with a thickness of 60 μm having corona-treated one side so that a coated film after drying became 3 μm, this was dried in a dryer at 80° C. for 3 minutes to form a pressure-sensitive adhesive layer, and to this was attached a polyethylene film having a surface roughness of Ra=0.01 μm and Rz=0.06 μm to obtain a surface protecting film.

Evaluation results of the above Examples 1 and 2, and Comparative Examples 1 to 3 are shown in Table 2.

TABLE 2

| | | | | Comp. | Comp. | Comp. |
|---|---|---|---|---|---|---|
| | | Ex. 1 | Ex. 2 | Example 1 | Example 2 | Example 3 |
| Glass transition | | −22.3 | −22.3 | −22.3 | −40.0 | −9.7 |
| temperature (° C.) of | | | | | | |
| copolymer | | | | | | |
| Initial adhering strength | | 0.34 | 0.33 | 0.11 | 2.3 | 0(No |
| (N/20 mm) | | | | | | adhesion) |
| Peeling strength | | 0.12 | 0.13 | 0.01 | 0.6 | 0(No |
| (N/20 mm) | | | | | | adhesion) |
| Measurement of | Ra | 0.05 | 0.06 | 0.20 | 0.06 | 0.07 |
| surface | Rz | 0.30 | 0.39 | 1.14 | 0.32 | 0.33 |
| roughness (μm) | | | | | | |
| Measurement of | Number/ | 515 | 251 | 4738 | 8007 | 492 |
| particulate | 78.5 cm² | | | | | |
| residues on | | | | | | |
| adherend | | | | | | |
| surface | | | | | | |

As shown by results of Table 2, in Examples 1 and 2, the number of particulate residues was small, and an initial adhering strength and a peeling strength were suitable. To the contrary, in Comparative Example 1 having a larger surface roughness, the number of particulate residues became about 10-fold, and an initial adhering strength and a peeling strength were not sufficient. In addition, in Comparative Example 2 in which a glass transition temperature was too low, the number of particulate residues was further increased and, in particular, there was a problem that a peeling strength becomes too high. Conversely, in Comparative Example 3 in which a glass transition temperature was too high, there was neither initial adhering strength nor peeling strength, and the film did not function as a protecting film.

In Examples of the present invention, since occurrence of particles can be prevented when a protecting film was peeled from a mother glass for a liquid crystal substrate, a yield in manufacturing of a liquid crystal panel could be improved. In particular, since occurrence of particles of 0.5 μm or larger could be prevented, remarkable improvement was possible as compared with usual.

1. A film for protecting a mother glass for a flat panel display having a pressure-sensitive adhesive layer on one side of a film substrate,
wherein a surface roughness Ra of the pressure-sensitive adhesive layer is 0.2 μm or smaller, and a surface roughness Rz is 1.0 μm or smaller,
and wherein the pressure-sensitive adhesive layer comprises a crosslinked copolymer containing a (meth)acrylic acid ester monomer and a vinyl-based monomer having a functional group as a component, and a glass transition temperature of the copolymer obtained by a Fox's equation is −25 to −10° C.:
1/Tg=Σ(Wn/Tgn) Fox's equation:
wherein Tg(K) represents a glass transition temperature of a copolymer, Wn(−) represents a weight fraction of each monomer, Tgn(K) represents a glass transition temperature of a homopolymer of each monomer, and n represents a kind of each monomer.

2. The film for protecting a mother glass for a flat panel display according to claim 1, wherein a separator having a surface roughness Ra of a releasing side of 0.2 μm or smaller and a surface roughness Rz of 1.0 μm or smaller is attached to the pressure-sensitive adhesive layer, and this is wound in a roll manner.

3. A method of conveying a mother glass for a flat panel display, which comprises attaching a pressure-sensitive adhesive side of a film for protecting a mother glass for a flat panel display as defined in claim 1 to at least one side of a mother glass for a flat panel display, and laminating a plurality of this to be conveyed.

4. The method of conveying a mother glass for a flat panel display according to claim 3, wherein when a plurality of mother glasses for a flat panel display with the protecting film attached thereto are laminated, an unevenly-processed film intervenes.

5. A mother glass for a flat panel display with a protecting film, characterized in that a pressure-sensitive adhesive side of a film for protecting a mother glass for a flat panel display as defined in claim 1 is attached to at least one side of a mother glass for a flat panel display.

6. A laminate of a mother glass for a flat panel display, wherein a pressure-sensitive adhesive side of a film for protecting a mother glass for a flat panel display as defined in claim 1 is attached to at least one side of a mother glass for a flat panel display, and a plurality of this are laminated.

7. A method of conveying a mother glass for a flat panel display, which comprises attaching a pressure-sensitive adhesive side of a film for protecting a mother glass for a flat panel display as defined in claim 2 to at least one side of a mother glass for a flat panel display, and laminating a plurality of this to be conveyed.

8. The method of conveying a mother glass for a flat panel display according to claim 7, wherein when a plurality of mother glasses for a flat panel display with the protecting film attached thereto are laminated, an unevenly-processed film intervenes.

9. A mother glass for a flat panel display with a protecting film, characterized in that a pressure-sensitive adhesive side of a film for protecting a mother glass for a flat panel display as defined in claim 2 is attached to at least one side of a mother glass for a flat panel display.

10. A laminate of a mother glass for a flat panel display, wherein a pressure-sensitive adhesive side of a film for protecting a mother glass for a flat panel display as defined in claim 2 is attached to at least one side of a mother glass for a flat panel display, and a plurality of this are laminated.
